(19) United States
(12) Patent Application Publication
(10) Pub. No.: US 2009/0104776 A1
(43) Pub. Date: Apr. 23, 2009

(54) METHODS FOR FORMING NESTED AND ISOLATED LINES IN SEMICONDUCTOR DEVICES

(75) Inventors: David M. Dobuzinsky, New Windsor, NY (US); Johnathan E. Faltermeier, Delanson, NY (US); Naoyoshi Kusaba, Hopewell Junction, NY (US); Joyce C. Liu, Carmel, NY (US); Munir D. Naeem, Poughkeepsie, NY (US); Siddhartha Panda, Kanpur (IN); Richard S. Wise, Newburgh, NY (US); Hongwen Yan, Somers, NY (US)

Correspondence Address: CANTOR COLBURN LLP - IBM FISHKILL, 20 Church Street, 22nd Floor, Hartford, CT, 06103, US

(73) Assignee: INTERNATIONAL BUSINESS MACHINES CORPORATION, Armonk, NY (US)

(21) Appl. No.: 11/874,392

(22) Filed: Oct. 18, 2007

(51) Int. Cl. H01L 21/4763

(52) U.S. Cl. 438/684; 257/E21.495

(57) ABSTRACT

A method for forming lines for semiconductor devices including, depositing a shallow trench isolation (STI) film stack on a silicon substrate, depositing a layer of polysilicon on the STI film stack, depositing a layer of antireflective coating on the layer of polysilicon, developing a phototoresist on the antireflective coating, wherein the photoresist defines a line, etching the layer of antireflective coating and the layer of polysilicon using RIE with a low bias power, removing the photoresist, removing the layer of antireflective coating, etching the STI film stack to form the line, wherein the layer of polysilicon further defines the line.

### BACKGROUND OF THE INVENTION

1. Field of the Invention

This invention relates generally to semiconductor device fabrication techniques, and particularly to a method for forming nested and isolated lines in semiconductor devices.

2. Description of Background

Structures in semiconductor devices are often connected with lines of conductive materials. A line may be an isolated line such that it is relatively isolated from other lines, or a nested line that is relatively close to other lines. FIG. 1 illustrates a scanning electron microscope (SEM) graphic of a prior art example of a top view of nested lines 102 and an isolated line 104 disposed on a substrate.

In fabrication, isolated lines and nested lines are often fabricated in the same steps. A hardmask of polysilicon may be used when reactive ion etching (RIE) the silicon to etch the material between the lines. The critical dimension (CD) is the smallest dimension of a structure of a semiconductor device. When using a polysilicon hardmask, the relatively small distance between nested lines compared to the distance between an isolated line and another line result in isolated lines having a different width than nested lines (i.e., a bias in width between the nested lines and the isolated lines and the CD). FIG. 2 illustrates a SEM graphic of a side partially cut-away view along lines A-A of FIG. 1 of the nested lines 102 and the isolated line 104. The width of the isolated line 102 is greater where the line contacts the substrate 106 and decreases in profile towards a top portion 108 of the isolated line 104.

The demand for semiconductor chips with smaller structures that are spaced closer together than previous structures results in a tapered profile of isolated lines becoming less desirable due to design constraints and the performance of isolated lines with tapered profiles. Additionally, creating narrow nested lines closer together is difficult using previous fabrication techniques and may result in a significant bias between the isolated and nested lines.

### SUMMARY OF THE INVENTION

The shortcomings of the prior art are overcome and additional advantages are achieved through a method for forming lines for semiconductor devices including, depositing a shallow trench isolation (STI) film stack on a silicon substrate, depositing a layer of polysilicon on the STI film stack, depositing a layer of antireflective coating on the layer of polysilicon, developing a phototoresist on the antireflective coating, wherein the photoresist defines a line, etching the layer of antireflective coating and the layer of polysilicon using RIE with a low bias power, removing the photoresist, removing the layer of antireflective coating, etching the STI film stack to form the line, wherein the layer of polysilicon further defines the line.

An alternate exemplary method for forming lines for semiconductor devices including, depositing a shallow trench isolation (STI) film stack on a silicon substrate, depositing a layer of polysilicon on the STI film stack, depositing a layer of antireflective coating on the layer of polysilicon, developing a phototoresist on the antireflective coating, wherein the photoresist defines an isolated line and a plurality of nested lines, etching the layer of antireflective coating and the layer of polysilicon using RIE with a low bias power, wherein the etching removes more of the polysilicon layer of the isolated line than the polysilicon layer of the plurality of nested lines, removing the photoresist, removing the layer of antireflective coating, and etching the STI film stack to form an isolated line and a plurality of nested lines, wherein the layer of polysilicon further defines the isolated line and the plurality of nested lines.

Additional features and advantages are realized through the techniques of the present invention. Other embodiments and aspects of the invention are described in detail herein and are considered a part of the claimed invention. For a better understanding of the invention with advantages and features, refer to the description and to the drawings.

### BRIEF DESCRIPTION OF THE DRAWINGS

The subject matter, which is regarded as the invention, is particularly pointed out and distinctly claimed in the claims at the conclusion of the specification. The foregoing and other aspects, features, and advantages of the invention are apparent from the following detailed description taken in conjunction with the accompanying drawings in which:

FIG. 1 illustrates an SEM graphic of a top view of a prior art example of nested and isolated lines.

FIG. 2 illustrates an SEM graphic of a partially cut-away side view of the nested and isolated lines of FIG. 1 along lines A-A.

FIGS. 3a-3f illustrate an exemplary method of forming isolated and nested lines.

FIG. 4 illustrates an exemplary graph of the CD bias of isolated and nested lines.

FIG. 5 illustrates an exemplary SEM graphic of a partially cut-away side view of nested and isolated lines.

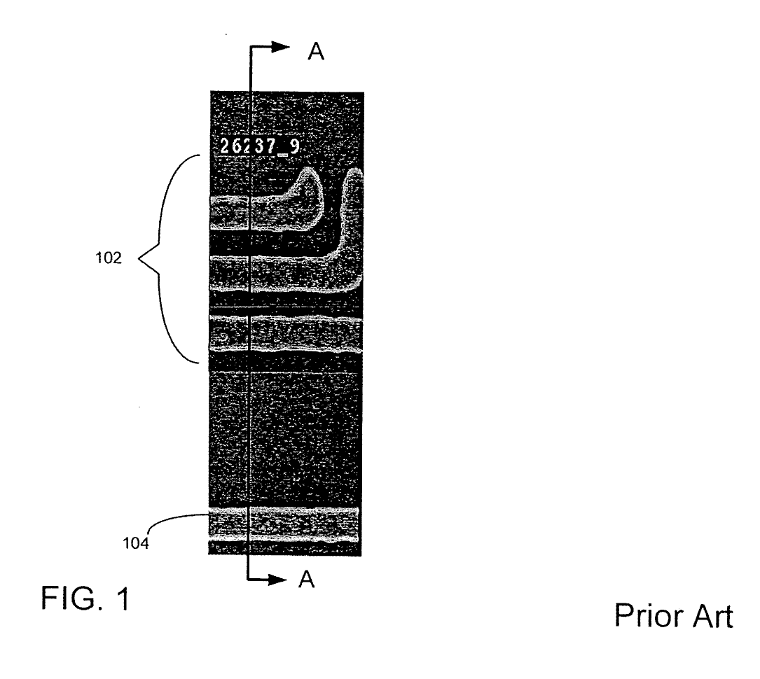

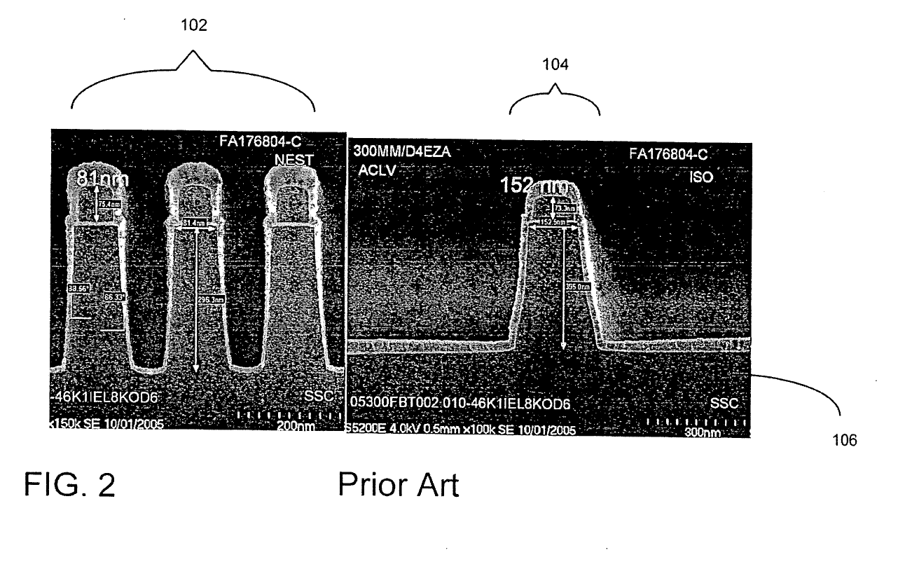

The detailed description explains the preferred embodiments of the invention, together with advantages and features, by way of example with reference to the drawings.

### DETAILED DESCRIPTION OF THE INVENTION

Methods of forming nested and isolated lines in semiconductor devices are provided. Several exemplary embodiments are described.

The smallest dimension for structures on a semiconductor device is called the critical dimension (CD). To make semiconductor devices smaller, they usually require the CD to be made smaller to allow for structures on the semiconductor to become smaller and spaced more closely together. Lines are structures on semiconductor chips that connect components on a semiconductor chip. Two types of lines are nested and independent. Nested lines are lines that are spaced relatively close to other lines and independent lines are spaced relatively far from other lines. The processes used to produce nested and independent lines form the lines at the same time, however since the nested lines are spaced closely to other lines, they form differently than independent lines. Generally independent lines have a higher width bias relative to the CD while the nested lines have a lower width bias relative to the CD. It is desirable to limit the width biases of nested and independent lines and make the widths of the lines more similar.

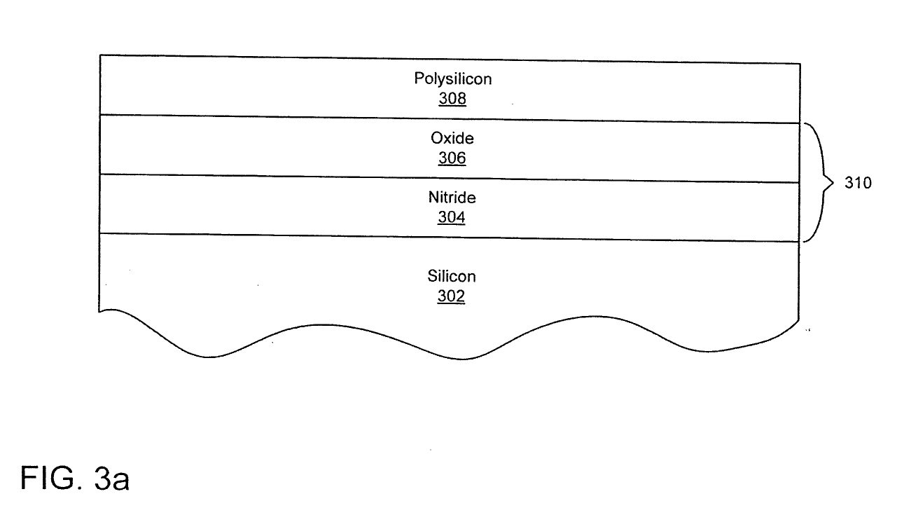

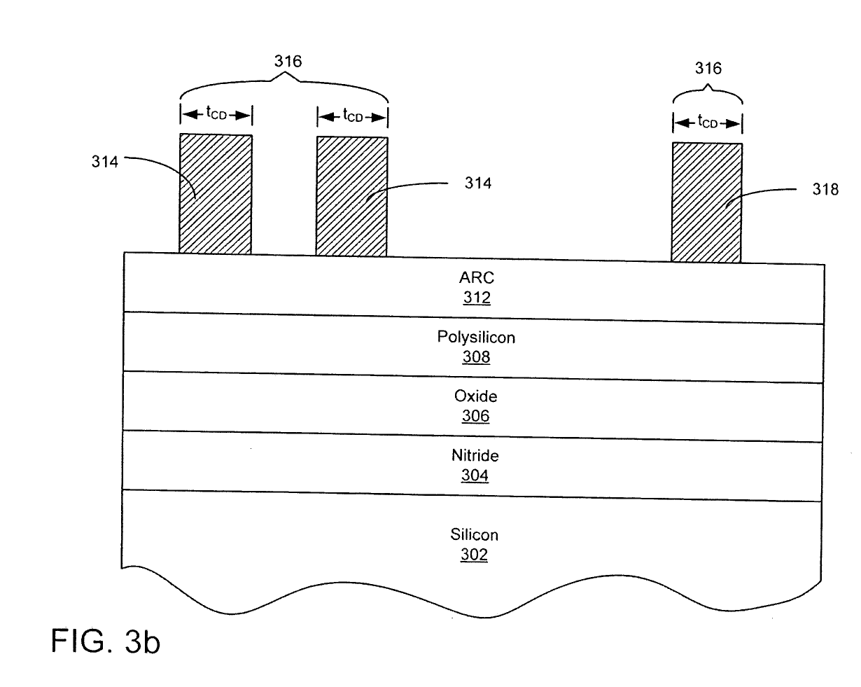

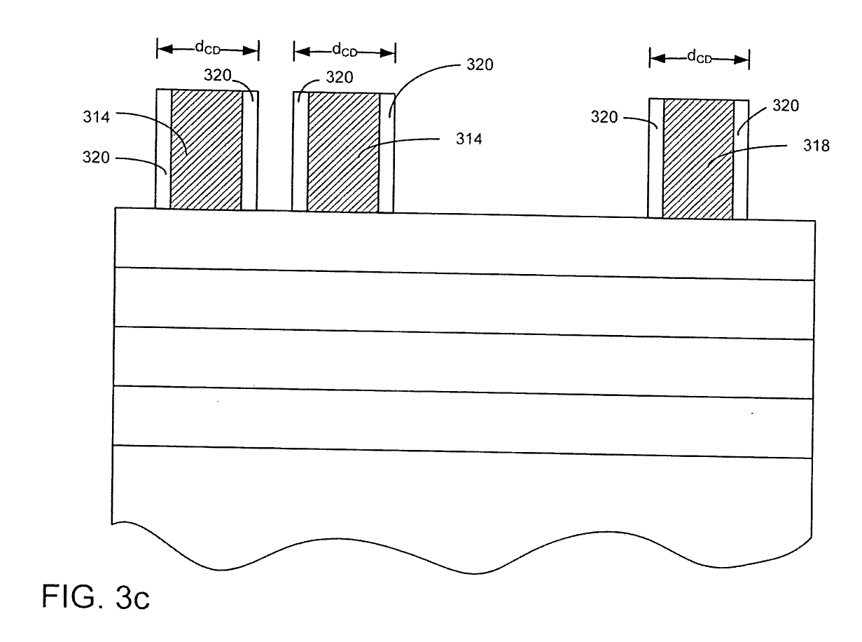

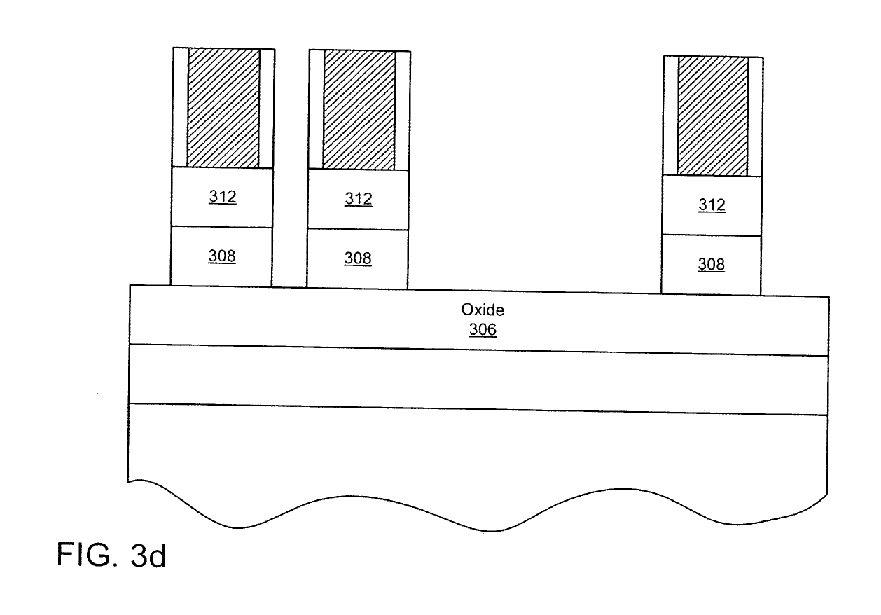

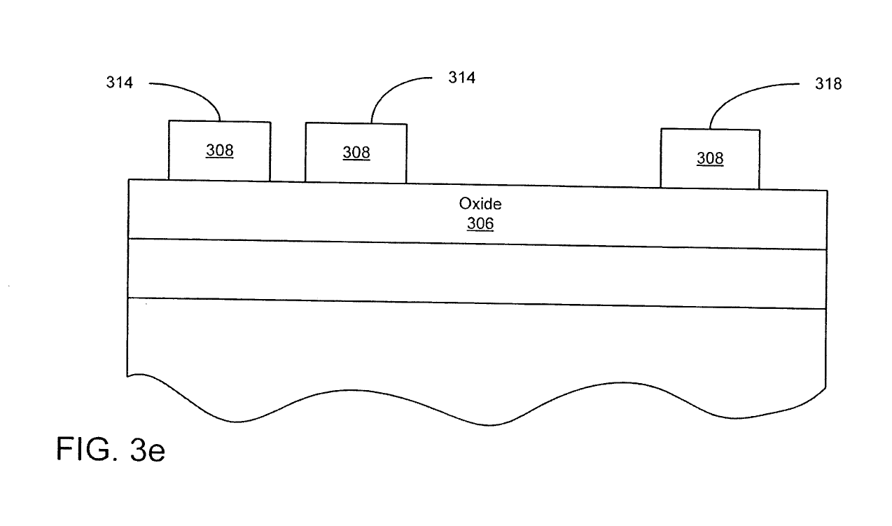

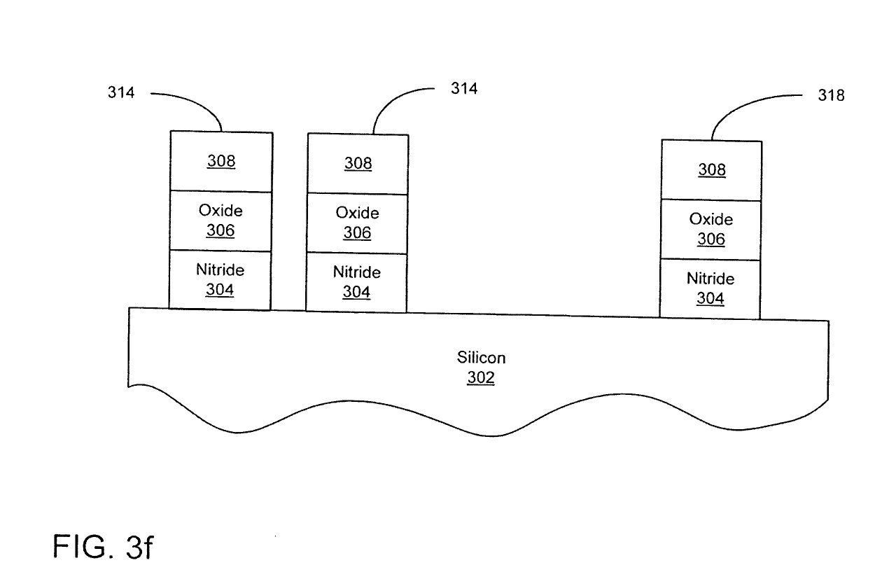

In this regard, referring to FIG. 3a, a nitride layer 304 is deposited on a substrate 302. The substrate 302 may include a doped bulk silicon substrate, a silicon-on-insulator (SOI) layer, or may not be doped. An oxide layer 306 is deposited on the nitride layer 304, and a polysilicon layer 308 is deposited on the oxide layer 306. A small layer of pad oxide (not shown) comprising, for example, SiO₂ may be disposed between the nitride layer 304 and the substrate 302. In this embodiment, the nitride layer 304 is approximately 100 nm thick, the oxide layer 306 is approximately 220 nm thick and the polysilicon layer 308 is approximately 100 nm thick.

In FIG. 3b an anti-reflective coating layer 312 is deposited on the polysilicon layer 308. A photoresist 316 has been developed on the anti-reflective coating layer 312. The photoresist 316 includes patterns that define the nested lines 314, and a pattern that defines an isolated line 318 at a target CD (t_{CD}).

FIG. 3c illustrates a polymer formed on the sidewalls of the photoresist patterns 316. The sidewall polymer film comprises, for example, carbon (C), hydrogen (H), and fluorine (F). The processing step illustrated in FIG. 3c effectively increases the CD width of the lithographic photoresist 316 used in etching the lines. The polymer film may be controlled in width from 0 nm to about 50 nm or more. This step may be implemented if the lithographic equipment used cannot print patterns that define the nested lines 314 and a pattern that defines an isolated line 318 at a designed CD (d_{CD}). Thus, if the lithographic equipment allows and can develop a photoresist or mask at the d_{CD}, the deposition of the polymer to the sidewalls of the photo resist may be omitted and the t_{CD} of FIG. 3b would equal the d_{CD}.

In FIG. 3d, reactive ion etching (RIE) is used to etch the anti-reflective coating layer 312 and the polysilicon layer 308. In the illustrated embodiment, the RIE is implemented using a low radio frequency bias of about 75 watts to perform the etch (although lower radio frequency biases may also be used). The resultant structure from the low radio frequency bias etch is that the CD of the polysilicon layer 308 in the nested lines 314 is trimmed at a slower rate than the CD of the polysilicon layer 308 in the isolated line 318. The result is that the polysilicon layer 318 of the isolated line 318 has a smaller CD than the polysilicon layer 308 of the nested lines 314.

FIG. 3e illustrates the resultant structure after the removal of the photoresist 316 and the anti-reflective coating layer 312. The polysilicon layer 308 acts as a hardmask that defines the nested lines 314 and isolated line 318.

An etch using a process such as, for example, RIE to form the nested lines 314 and isolated line 318 is performed using the polysilicon layer 308 as a hardmask. FIG. 3f illustrates the resultant structure following the etch. The structure includes nested lines 314 and isolated line 318 each having the nitride layer 304 disposed on the substrate 302, the oxide layer 306 disposed on the nitride layer 304, and the polysilicon layer 308 disposed on the oxide layer 306.

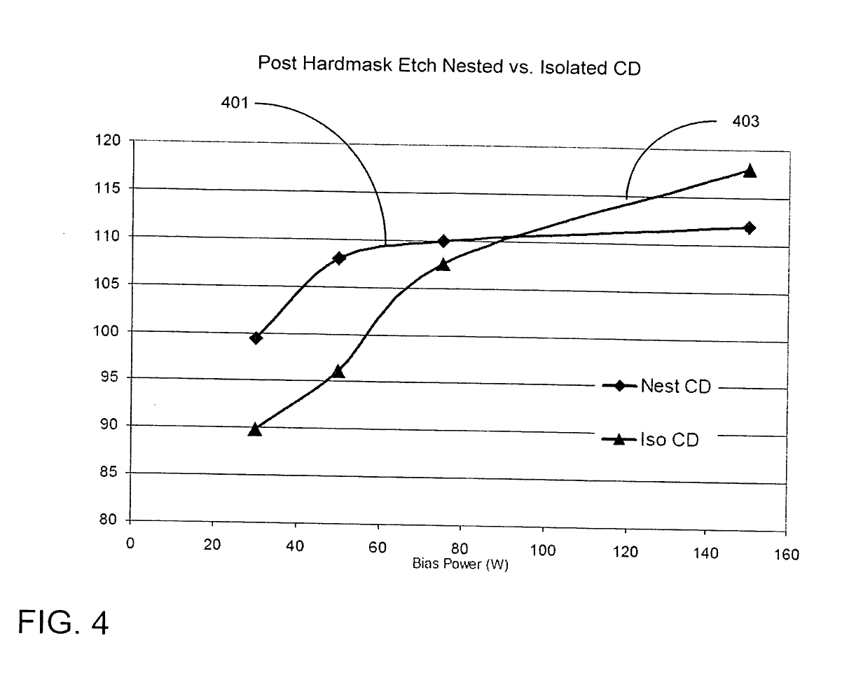

FIG. 4 illustrates a graph having a nested line CD curve 401 and an isolated line CD curve 403. In this exemplary embodiment, the differences in the bias of the nested lines and isolated lines are illustrated at different radio frequency bias power levels for the RIE etch.

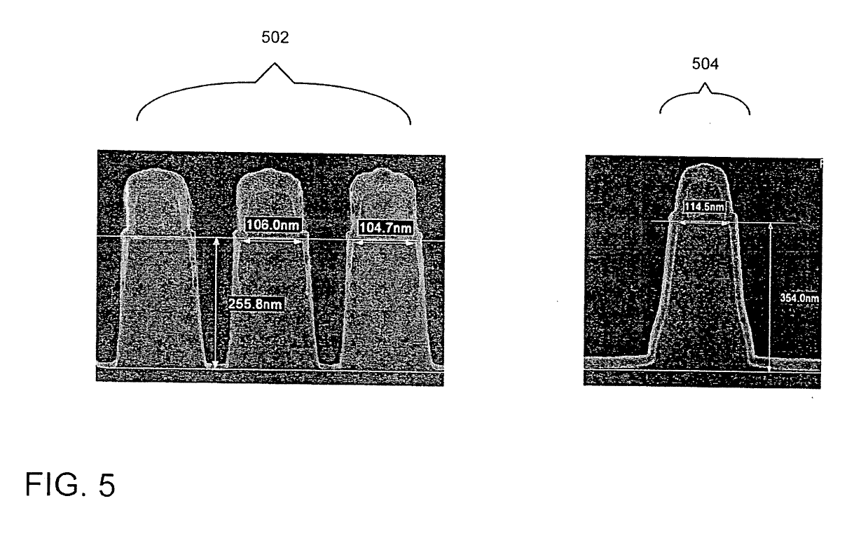

FIG. 5 illustrates an exemplary SEM graphic of a partially cut-away side view of nested and isolated lines resulting from the exemplary method of FIGS. 3a-3e. In this regard, the nested lines 502 are similar in width to the isolated line 504.

While the preferred embodiment to the invention has been described, it will be understood that those skilled in the art, both now and in the future, may make various improvements and enhancements which fall within the scope of the claims which follow. These claims should be construed to maintain the proper protection for the invention first described.

1. A method for forming lines for semiconductor devices, the method comprising:
depositing a shallow trench isolation (STI) film stack on a silicon substrate;
depositing a layer of polysilicon on the STI film stack;
depositing a layer of antireflective coating on the layer of polysilicon;
developing a phototoresist on the antireflective coating, wherein the photoresist defines an isolated line and a plurality of nested lines;
etching the layer of antireflective coating and the layer of polysilicon using RIE with a bias power such that the etching removes the polysilicon layer of the isolated line at a faster rate than the polysilicon layer of the plurality of nested lines;
removing the photoresist;
removing the layer of antireflective coating; and
etching the STI film stack to form an isolated line and a plurality of nested lines, wherein the layer of polysilicon further defines the isolated line and the plurality of nested lines.

2-12. (canceled)
